(19) United States
(12) Patent Application Publication
(10) Pub. No.: US 2006/0286716 A1
(43) Pub. Date: Dec. 21, 2006

(54) Flip-chip mounting electronic component and method for producing the same, circuit board and method for producing the same, method for producing package

(75) Inventor: Toshiharu Takayama, Ina (JP)

Correspondence Address: PATENT DOCKET CLERK;COWAN, LIEBOWITZ & LATMAN, P.C., 1133 AVENUE OF THE AMERICAS, NEW YORK, NY, 10036, US

(73) Assignee: K-TEC DEVICES CORP., Nagano (JP)

(21) Appl. No.: 10/538,584

(22) PCT Filed: Dec. 18, 2002
(86) PCT No.: PCT/JP02/13203

§ 371 Date: Mar. 9, 2006

(51) Int. Cl. H01L 21/00; H01L 23/48

(52) U.S. Cl. 438/108; 257/778

(57) ABSTRACT

A method for producing a flip-chip mounting electronic component having plural terminals (3) dotted on a mounting face (1) and conductors formed on the terminals (3) realizes flip-chip mounting capable of shortening the distance between bumps (7). To realize this, a step of coating the mounting face (1) with a conductor having a predetermined thickness, a step of masking corresponding positions for the terminal (3) parts on the conductor surface, and a step of removing the conductor except the mask (6) parts are included and performed in this order. The bump is preferably constituted of copper.

### TECHNICAL FIELD

The present invention relates to a flip-chip mounting electronic component and a method for producing the same, a circuit board and a method for producing the same, and a method for producing a package.

### BACKGROUND ART

Along with miniaturization of electronic apparatuses in recent years, mounting of electronic components with high density is demanded, and there is a flip-chip mounting technique as one of techniques for responding to such a demand. A flip-chip mounting electronic component has a mounting side face that is dotted with plural solder bumps, and when mounting this electronic component, the solder bumps are melted and fixed to lands of a circuit board.

In order to form the solder bumps on an electronic component, it is common that solder balls are arranged at necessary positions on a mounting face of the flip-chip mounting electronic component and subjected to a reflowing step or the like.

When the aforementioned mounting with high density is further advanced, it is conceivable that miniaturization of the flip-chip mounting electronic component by reducing the distance between separate solder bumps is demanded next. Accordingly, an object to be achieved by the present invention is to realize flip-chip mounting with a shortened distance between bumps.

### DISCLOSURE OF THE INVENTION

In order to achieve the above-described object, a method for producing a flip-chip mounting electronic component according to the present invention is a method for producing a flip-chip mounting electronic component having plural terminals 3 dotted on a mounting face 1 and conductors formed on the terminals 3, including the steps of: coating the mounting face 1 with a conductor having a predetermined thickness; masking corresponding positions for the terminal 3 parts on the conductor surface; and removing the conductor except the mask 6 parts, in which these steps are performed in this order.

The step of coating the mounting face 1 with a conductor having a predetermined thickness is, for example, an electroless plating step and an electrolytic plating step. For example, on an insulation portion surface and terminals 3 of a printed circuit board 8 shown in FIG. 1A, an electroless plating layer 4 constituted of copper is formed (FIG. 1B), and thereafter an electrolytic plating layer 5 constituted of copper is formed further (FIG. 1C). The step of masking corresponding positions for the terminal 3 parts on the conductor surface is a step of forming the masks 6 by a screen printing technique or the like for example at the corresponding positions for the terminals 3 on the surface of the electrolytic plating layer 5 constituted of copper that is conductor for example (FIG. 1D). The step of removing the conductor portions except conductor portions where the masks 6 are arranged is carried out by soft etching for example. Thus, the electrolytic plating layer 5 and the electroless plating layer 4 are removed except covered by the masks 6 (FIG. 1E). Thereafter, the masks 6 are removed as necessary (FIG. 1F). This removing is not necessary for masks 6 constituted of a material that melts slowly during the soft etching or if a good mounting state can be maintained when mounting even with remaining masks 6. Examples of removing methods include a process with acid or alkali, a peeling process, a grinding process, and the like. For example, when photosensitive ink is adopted as the material of the masks 6 formed by the screen printing technique, it is removed by an alkaline chemical or the like.

When the above steps shown in FIGS. 1A to 1F are performed in this order, bumps 7 as conductors (copper) are formed. In these steps, it is clear that the distance between bumps 7 can be made very narrow as compared to prior arts because the steps shown in FIGS. 1A to 1F use a technique similar to the technique for a patterning step of a printed circuit board. In the patterning technique of a printed circuit board, so-called fine pitch patterning is possible, which is capable of forming the bumps 7 at approximately 0.05 m intervals. This is narrower than a typical shortest distance between bumps (0.25 to 0.75 mm) in conventional bump formation which fixes with solder balls. Moreover, the bump diameter is conventionally 0.3 to 1.0 mm, which can be approximately 0.1 mm by the present invention. Therefore, the flip-chip mounting with the distance between bumps 7 being made smaller becomes possible, which is the object to be achieved by the present invention. Furthermore, this enables miniaturization of the flip-chip mounting electronic component.

The bumps 7 obtained through the steps shown in FIGS. 1A to 1F each have a substantially flat tip. Accordingly, for example, when using the bumps 7 made of a material (made of copper for example) which does not change in shape before and after a mounting step using solder, a contact area between the melted solder and the tip face and its surrounding side face of a bump 7 becomes larger than the case of using conventional spherical bumps 7, and it is largely affected by surface tension of the melted solder, thereby improving so-called self alignment ability. Further, when the bumps 7 constituted of solder are used, it is possible to suppress change in shape of the bumps 7 as much as possible while they melt and solidify. On the contrary, when conventional solder balls are used, large change in shape during melting and solidifying processes is inevitable while mounting because the face of a solder ball in contact with a circuit board (exactly a land) is initially spherical and then becomes flat during the subsequent melting and solidifying processes. Depending on the magnitude of such an amount of change in shape of solder while mounting, adjacent bumps may solidify in a contact/integrated state when they are in the melted state and their shapes are being changed. It is occurrence of a phenomenon similar to a so-called solder bridge. In this point of view, if the amount of change in shape of solder while mounting can be suppressed minimally, contact of adjacent solder bumps in the melting and solidifying processes of the solder bumps can be suppressed. According to these facts, both when the bumps 7 are made of a material other than solder such as copper and when the bumps 7 are solder, the tip thereof is preferred to be substantially flat.

Through the steps shown in FIGS. 1A to 1F, it is possible to obtain a flip-chip mounting electronic component according to the present invention, which has plural terminals dotted on a mounting face 1 and conductors formed on the terminals, in which the conductors are formed as remaining parts from growing formation and removal, all the sums of heights of the terminals and the conductors thereon are substantially equal, and tips of the conductors have a substantially flat face.

Through the steps shown in FIGS. 1A to 1F, it is possible to obtain a circuit board according to the present invention, which has plural flip-chip mounting lands dotted on a mounting face 1 and conductors formed on the terminals, in which the conductors are formed as remaining parts from growing formation and removal, all the sums of heights of the lands and heights of the conductors thereon are substantially equal, and tips of the conductors have a substantially flat face.

Also, the bumps 7 according to the present invention can be electrically connected to a circuit board via an anisotropic conductive material 2 without melting and solidifying the bumps 7 when mounting. The anisotropic conductive material 2 is preferred to be in a paste form and capable of solidifying thereafter because it also has a fixing function and has no difficulty of handling like the solder, such that a solid matter does not move and flow without heating and melting. By mounting using the anisotropic conductive material 2, the distance between adjacent bumps 7 can be made smaller as compared to mounting using solder because there is no material (conventional solder for example) having probability of conduction between adjacent bumps 7. In this case, it can be said that the method for producing bumps 7 according to the present invention is particularly preferable because they are produced by the fine pitch patterning technique as described above, and the distance between adjacent bumps 7 can be made smaller to be the equivalent level to a current printed circuit pattern interval. In this case, the material of the bumps 7 is preferred to be copper for example because it has high conductivity and is cheap and easily obtainable.

Heights of all the plural bumps 7 (in FIG. 1F, the sums of the terminals 3 and the electrolytic plating layers 5) according to the present invention are preferred to be substantially equal because an even and secure electrical connection state of all the bumps 7 can be obtained at all electrical connection positions by mounting on same contact state with the circuit board. When composing a package according to the present invention using the anisotropic conductive material 2 as described above, it is particularly important to make heights of the bumps 7 substantially equal because the difference between respective bumps 7 in the compressed state of the anisotropic conductive material 2 compressed by the bumps 7 directly generates dispersion in electrical connection state of each bump 7. In the electrolytic plating layer 5 forming step according to the present invention, electrolytic plating is performed on the entire face of the printed circuit board 8 and the terminals 3. Except the case where surface conditions of the printed circuit board 8 and the terminals 3 as the base thereof are extremely uneven, all heights of the electrolytic plating layer 5 become substantially equal. Since thicknesses of the terminals 3 barely affect the electrolytic plating step and are thus ignorable and the affected portions are already removed at the time when unnecessary portions are removed finally and the bumps 7 remain, the heights of all the plural bumps 7 according to the present invention become substantially equal.

Shapes of the bumps 7 are preferred to be a truncated cone or a truncated pyramid with a small tip because it can make the distance between tips of adjacent bumps 7 long while the overall strength of the bumps 7 is maintained by their base portions (the opposite side of the tip). This contributes further to prevention of conduction between the bumps 7. Also, in the case where the mask 6 is formed by screen printing or the like when forming the bumps 7, displacement of their positions can be tolerated to a certain degree.

When the tips of the bumps 7 and portions for them to be connected are fixed by a thermocompression bonding method, the aforementioned bump formation (in a truncated cone or truncated pyramid shape) is particularly preferred. Here, the thermocompression bonding method refers to a method for fixing the both by pressurizing in a heated state, or a method for fixing the both by further pressurizing in a heated state and additionally applying vibration by ultrasonic waves or the like. In such a thermocompression bonding method, the aforementioned bump shape facilitates concentration of a pressure at the tip of a bump, and its base portion has a wide width that conversely disperses the pressure. Such a base portion is required to have fixing strength between a bump 7 and its support portion particularly in the thermocompression bonding method. Thus including conditions required respectively for the base portion and the tip of the bump 7, it can be said that the truncated cone or the truncated pyramid is the suitable shape of the bump 7 for the thermocompression bonding method. When adopting the thermocompression method, it is preferred that a material which melts relatively easily and hardens immediately thereafter is arranged at least on the tip surface of the bump 7. This material is, for example, solder, gold and the like.

Formation of the electrolytic plating layer 5 is one type of growing formation. Specific examples of other growing formation include CVD, sputtering, evaporative decomposition, and so on, but among them, plating methods are preferred because they are better in terms of growth speed, efficiency, accompanying cost reduction and the like as compared to other methods. Among them, electrolytic plating methods are particularly preferred because they provide fast growth speed. Instead of the growing formation, it is also possible to form the bumps 7 as remaining parts from removal. For example, a conductive material in a foil form is attached on the printed circuit board 8, and thereafter unnecessary portions are removed by etching or the like. Formation of the bumps 7 shown in FIGS. 1A to 1F is carried out by means of both the growing formation by electrolytic plating and removal by soft etching or the like. Typically, formed objects (bumps 7) obtained by the growing formation such as electrolytic plating are fixed strongly to the surface of a base thereof (a terminal 3 of the printed circuit board 8), and has an advantage of excellent handling capability. Similarly to the case of using conventional solder balls, there is also an advantage that no complicated step is required, such as fixing an object that is initially a separate member.

The bumps 7 may be formed on the electronic component side, on a circuit board on which the electronic component is to be mounted, or on both the electronic component side and the circuit board. The material of the bumps 7 may be other than the copper, which may be a solder for example. In this case, the solder can be used as a fixing material when composing the flip-chip package. This point is the same as when conventional solder balls are used. In this case, cream solder may be used as an assisting connection member when mounting for further assuring electrical connection between the circuit board and the electronic component and for improving connection strength thereof.

As the bumps 7, the fixing material, and the cream solder, it is possible to use one selected from Pb—Sn based alloy, single Sn, Sn—Bi based alloy, Sn—In—Ag based alloy, Sn—Bi—Zn based alloy, Sn—Zn based alloy, Sn—Ag—Bi based alloy, Sn—Bi—Ag—Cu based alloy, Sn—Ag—Cu based alloy, Sn—Ag—In based alloy, Sn—Ag—Cu—Sb based alloy, Sn—Ag based alloy, Sn—Cu based alloy, and Sn—Sb based alloy.

When the bumps 7 are mainly constituted of a material other than solder (copper for example), and the bumps 7 and portions for them to be connected are by melting and solidifying of solder, it is preferred that a layer for preventing a so-called solder erosion is formed on the bump surface, considering the case where the bump shape is desired to be maintained as much as possible for stabilizing a mounting state thereof. Such stabilizing of a mounting state is required particularly when mounting a small component. A typical example of such a layer is a nickel layer. When such metal that is not easily alloyed with solder is adopted as the main constituting material of the bumps 7, such a layer for preventing the solder erosion is unnecessary. Typical examples of metal which is easily corroded by solder include silver, copper, and gold. However, the above-described facts apply to the case of solder including tin. When solder not including tin is used, a solder erosion preventing layer material that is suitable for the solder constituent is selected.

It is further preferred that a layer having good affinity with solder is formed on such a solder erosion preventing layer. Such a layer is solder having the same constituent as the above solder, gold, silver, copper, or the like. In other words, it is a metal layer which is easily alloyed with solder because presence of this layer makes fixation with solder strong.

It is preferred that these solder erosion preventing layer and layer having good affinity with solder are formed by means of an electrolytic plating technique. It is said that by means of such a technique, an alloy layer constituted of highly dense elements of respective metal layers are formed at a joining face of the respective metal layers, and that affinity of each layer becomes excellent. However, in view of simplicity of production, the electroless plating technique is preferred because it does not require various types of wiring needed for the electrolytic plating. Here, a precipitation reaction mechanism required for an electroless plating solution is progress of the precipitation by local battery reaction at the surface of a material being plated. Thus, the precipitation to the insulation region between bumps can be prevented, and short-circuiting does not occur.

It is needless to mention that the flip-chip mounting electronic component having the bumps according to the present invention can be preferably used for a small electronic apparatus using a package which is mounted with high density. Also, for an apparatus such as an IC card in which a single flip-chip mounting electronic component is often used, the flip-chip mounting electronic component can be preferably used utilizing its characteristic of miniaturization.

### BRIEF DESCRIPTION OF THE DRAWINGS

FIGS. 1A to 1F are views showing one example of a condition of growing formation of bumps according to the present invention;

FIGS. 2A to 2C are views showing a main mounting part according to the present invention;

FIGS. 3A to 3D are schematic views of an electronic component according to the present invention, in which FIGS. 3A and 3B show a side cross section of the electronic component, FIG. 3C shows the side face of the electronic component, and FIG. 3D shows a back face of the electronic component; and

FIGS. 4A to 4E are views describing a fourth embodiment of the present invention.

Numerals used in these views are 1 . . . mounting surface, 2 . . . anisotropic conductive material, 3 . . . terminal, 4 . . . electroless plating layer, 5 . . . electrolytic plating layer, 6 . . . mask, 7 . . . bump, 8 . . . printed circuit board, 9 . . . electronic component, 10 . . . die adhesive, 11 . . . metal wire, 12 . . . filler, 13 . . . electrode, 14 . . . common electrode, 15 . . . resistor, 16 . . . glass, 17 . . . trimming trench, 18 . . . over coat, 19 . . . ceramics plate, 20 . . . land, 21 . . . gold layer, 22 . . . nickel layer, 23 . . . solder, and 24 . . . inner wiring bump.

### BEST MODE FOR CARRYING OUT THE INVENTION

### Embodiment 1

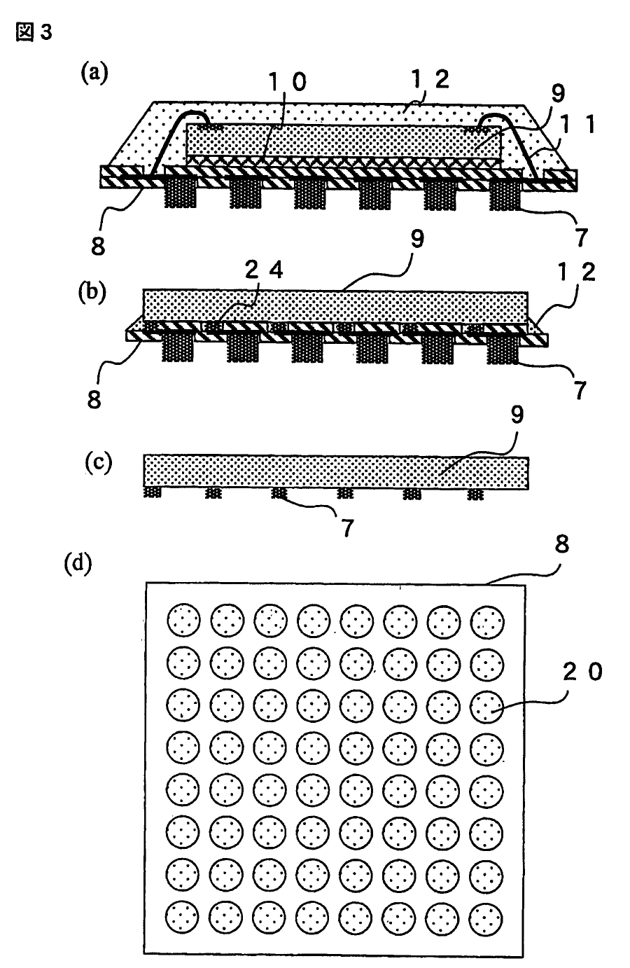

First, there is prepared a printed circuit board 8 in which plates as epoxy resin formed bodies including glass fiber mixed therein are layered. On the printed circuit board 8, a large number of terminals lead out from an electronic component 9, which will be described later, is formed via an inner layer having respectively independent conducting paths from one face to the other face, and on the other face, a large number of lands corresponding to the large number of terminals is dotted almost entirely thereon with insulation from each other being maintained (FIGS. 3A and 3D). A method for growing and forming bumps 7 constituted of copper starting from the lands will be described below.

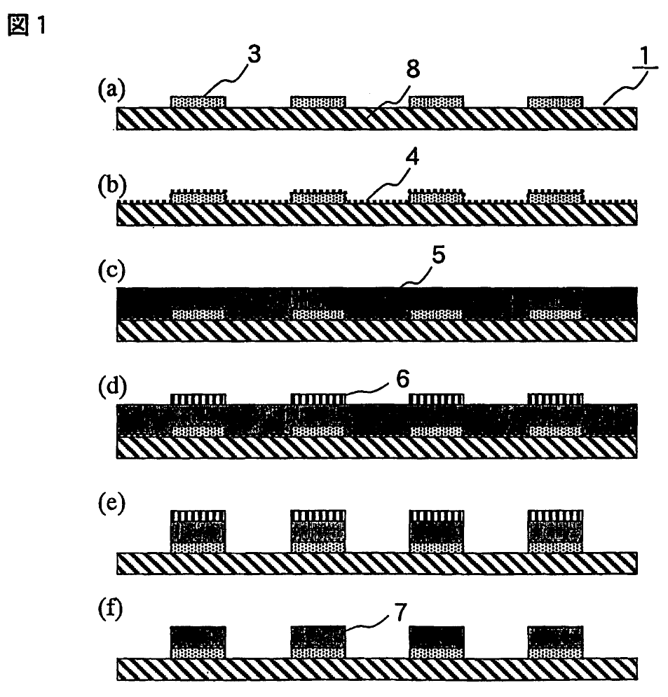

First, as shown in FIG. 1A, an electroless plating layer 4 constituted of copper is formed on an insulation portion and terminals 3 of the printed circuit board 8 (FIG. 1B). The method of electroless plating is so-called non-catalytic chemical plating, which is a method to dip a plating material (the printed circuit board 8) in a plating solution in which copper is dissolved. For this purpose, the composition of the plating solution includes a copper ion source, an alkali source, a reducing agent, a chelating agent, and the like. For these, commercially available ones can be used. By this plating, copper is formed on the lands and also on an insulation region between adjacent lands. A plating thickness thereof is approximately 0.2 μm. Incidentally, prior to this electroless plating, a plating catalyst such as palladium may be deposited.

Thereafter, an electrolytic plating layer 5 constituted of copper is formed further (FIG. 1C). The condition of electrolytic plating is such that, while dipping the printed circuit board after completing the above-described electroless copper plating step in a plating solution including copper pyrophosphate, an electric current is conducted with the terminals 3 of the printed circuit board 8 being cathodes until a plating thickness of approximately 250 μm is obtained.

Next, corresponding positions for the terminal 3 parts on the conductor surface are masked. It is a step of forming masks 6 each having a thickness of approximately 20 μm constituted of epoxy based resin by a screen printing technique at the corresponding positions for the terminals 3 on the surface of the electrolytic plating layer 5 (refer to FIG. 1D). The diameter of the masks was set to approximately ½ of the diameter of the lands. Thereafter, the paste is cured by heating. Minute protrusions and recesses on the surface of the electrolytic plating layer 5 due to the previous electrolytic plating step did not cause any adverse effect on this screen printing step.

The step of removing the conductors (the electrolytic plating layer 5 and) except the mask 6 parts is by soft etching using an iron chloride aqueous solution. Then, portions of the electrolytic plating layer 5 and the electroless plating layer 4 covered by the masks 6 remain (refer to FIG. 1E). Also, insulation between adjacent terminals is maintained.

Subsequently, the masks 6 are removed (refer to FIG. 1F). The removing method is a process of grinding the entire surface. With this grinding step, even if there are some protrusions and recesses on the electrolytic plating layers 5, all the sums of heights of the electrolytic plating layers 5 and the terminals 3 can be made substantially equal. It is also preferred to carry out the removal of the masks 6 by peeling means in view of simplifying the step. As a chemical for peeling in this case, normally a chemical capable of dissolving the mask 6 itself is selected. Furthermore, it may be performed such that the masks 6 are formed by attaching an adhesive sheet and then dipped in a chemical for dissolving this adhesive to thereby peel them off. For peeling these masks 6, it is preferred that the surface of the electrolytic plating layer 5 is relatively smooth.

Thus, bumps 7 are formed as remaining parts from growing formation and removal. The bumps 7 formed in this manner are fixed very securely to the printed circuit board 8 (exactly the terminals 3). The surface of the printed circuit board 8 on which the bumps 7 exist is a mounting face 1. Further, the bumps 7 became substantially truncated cone shapes with a small tip. Here, the diameter of the tip was ⅓ of the base portion of the bumps 7.

Subsequently, only on surfaces of the bumps, electroless nickel plating and electroless gold plating are performed in this order. The electroless nickel plating and the electroless gold plating are each performed by publicly known substitution plating.

Next, a method for attaching the electronic component 9 on the reverse face of the mounting face 1 of this printed circuit board will be described. A die adhesive 10 in a paste form (for example, “Chemi-tight CT200 series” made by Toshiba Chemical Corporation, or the like) shown in FIG. 3A is used to fix the electronic component 9 (an IC chip) in a flat cube shape on the reverse face of the mounting face 1 of the printed circuit board 8. Then, the electronic component 9 and lands of the printed circuit board 8 on the periphery thereof are connected electrically by a large number of metal wires 11. For this connection, a publicly known wire bonding technique is used. Furthermore, the entire metal wires 11 and the electronic component 9 are sealed by a filler 12 constituted of epoxy resin. Thus, the electronic component 9 is attached to the printed circuit board 8 and fixed thereto while maintaining an intended electrical connection state. The electronic component obtained in this manner is a flip-chip mounting electronic component according to the present invention.

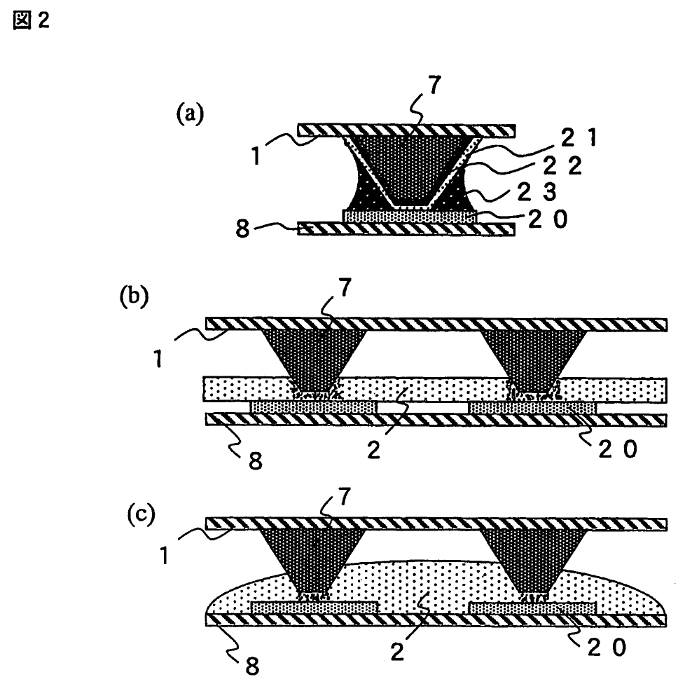

Next, a method for mounting the electronic component 9 that is attached to the printed circuit board 8 to a circuit board (a method for producing a package) will be described. Cream solder is screen printed on lands (made of copper) of the circuit board shown in FIG. 2A, which is then subjected to reflowing for melting and solidifying the cream solder to thereby fix the solder to the lands. At this time, the melted cream solder spread across the entire Au layer on the surface of each bump 7 and then solidified while holding the entire bump 7. Then, a fillet of solder is formed as shown in FIG. 2A, and there was no problem in fixing strength thereof. Such a fillet is mainly formed on a small portion of each bump 7 in a truncated cone shape, so that the melted solder solidified without flowing out of a land region, and there was no solder bridge formed between adjacent lands. Also, due to the affinity between the solder and the lands, formation of a solder bridge between adjacent lands is prevented. Such a method for producing a package is an example of the method for producing a package according to the present invention.

In this embodiment, screen printing is adopted as the forming method of the mask 6, but it is needless to mention that the forming method is not limited thereto. For example, a method of attaching a resin film, a method of exposing a photosensitive resin by a photographic technique, a method for forming a film by a so-called spinner technique, a method for forming a film by a so-called curtain coater technique, or the like may be adopted.

### Embodiment 2

Next, an embodiment in which bumps 7 are formed on a circuit board side on which an electronic component is attached (mounted) will be described. In the embodiment 1, the electronic component 9 (an IC chip) is fixed using the die adhesive 10 in a paste form on the reverse face of the printed circuit board 8 face on which the bumps 7 are formed, thereby realizing production of the electronic component 9 having the bumps 7. In this example, forming of the bumps 7 on the printed circuit board 8 in the embodiment 1 is adopted as it is. Then, an electronic component on which the bumps 7 are not formed and the printed circuit board 8 on which the bumps 7 are formed are fixed with each other by solder or the like.

A small amount of cream solder is screen printed on each bump 7 of the printed circuit board 8 obtained through the same process as in FIGS. 1A to 1F. The cream solder is arranged only on the top surface of each bump 7. In this state, the cream solder is brought into contact with terminals (lands) constituted of copper of the electronic component. Specifically, the electronic component is placed on the bumps 7. Thereafter through a reflowing step, the cream solder and the bumps 7 are melted and solidified, thereby composing a package. Alternatively, instead of the cream solder, only flux is applied on land surfaces and bump surfaces, which are subjected to reflowing thereafter for melting and solidifying the bumps constituted of solder, thereby fixing the solder to the lands. The melted solder solidified without flowing out of a land region due to its affinity with the lands, so that there was no solder bridge formed between adjacent lands. Such a method for producing a package is an example of the method for producing a package according to the present invention.

### Embodiment 3

Next, an example of the case that the bumps 7 are solder will be described. In this example, when forming the bumps 7 on the printed circuit board 8 in the embodiment 1 or embodiment 2, the electrolytic plating layer 5 (FIG. 1C) is formed by electrolyzing with the printed circuit board 8 being a cathode in a plating bath of aqueous solution in which alkanol sulfonic acid, stannous alkanol sulfonic acid, lead alkanol sulfonic acid are dissolved. Besides that, the bumps 7 are formed through the same steps as in the embodiment 1 and embodiment 2. However, nickel plating and gold plating are not performed on surfaces of the bumps 7. Similarly to the case of the embodiment 1, the solution for the soft etching is an iron chloride aqueous solution.

When mounting, cream solder is used, and the bumps 7 constituted of the solder are melted and solidified through a reflowing step, thereby fixing the electronic component 9 to the printed circuit board 8. As the amount of the cream solder, an amount so small as to cover only the top of a bump 7 is sufficient. However, even if some excessive amounts of cream solder exist, the melted solder solidified without flowing out of a land region due to its affinity with the lands, so that there was no solder bridge formed between adjacent lands.

Alternatively, instead of the cream solder, only flux is applied on land surfaces and bump surfaces, which are subjected to reflowing thereafter for melting and solidifying the bumps constituted of solder, thereby fixing the solder to the lands. Also in this case, the melted solder solidified without flowing out of a land region due to its affinity with the lands, so that there was no solder bridge formed between adjacent lands.

In the embodiment 3, an iron chloride aqueous solution is used as the etching solution for etching the solder, but it is needless to mention that the present invention is not limited to this. For example, an etching solution that is optimum for the composition of solder, its producing condition, and the like can be selected from iron chloride nitric acid solution, copper chloride aqueous solution, copper chloride nitric acid solution, methansulfonic acid aqueous solution, nitric acid aqueous solution, sulfuric acid, and the like.

In the embodiments 1 to 3, electrical connection was obtained by fixing the bumps 7 and the lands with each other by solder, but an anisotropic conductive material 2 (for example, “TAP/TNP series” made by Toshiba Chemical Corporation, or the like) in a paste or sheet form may be used to fix the electronic component 9 to the printed circuit board 8 (FIGS. 2B and 2C). When using one in a paste form, the paste is brought into a half-cured state by heating or the like, and thereafter portions of the paste between terminals of the electronic component 9 and the lands of the printed circuit board 8 are pressurized and compressed. Thus, portions originated from the projecting shape of the bumps 7 are particularly compressed and become good conducting regions, and in comparison, the other portions become poor conducting regions (FIG. 2C: dots in compressed portions are drawn densely). When using the anisotropic conductive material 2 in a sheet form, the anisotropic conductive material 2 is compressed between the bumps 7 and the lands, and while this state is maintained, the both of them are fixed with each other by sealing a gap thereof with resin or the like (not shown) (FIG. 2B). The compressed portions become good conducting regions, and in comparison, the other portions become poor conducting regions. Due to the presence of the poor conducting regions, conduction (short circuit) between adjacent bumps is avoided. Also, due to the presence of good conducting region, connection between the terminals of the electronic component and the lands of the printed circuit board 8 is realized. Such a method for producing a package is an example of the method for producing a package according to the present invention.

In the embodiments 1 to 3, the electronic components of the type in which inner wiring is achieved by wire bonding are used, but these are not limited thereto. For example, it may be a type in which inner wiring is achieved by inner wiring bumps as shown in FIG. 3B, or a type in which inner wiring is omitted and the inner wiring bumps shown in FIG. 3B are used as they are as the bumps according to the present invention for external wiring (FIG. 3C).

It is also possible that, after forming a circuit element such as a resistor element on a ceramic substrate surface instead of the printed circuit board 8, the bumps 7 according to the present invention are formed as terminals. Hereinafter, an embodiment 4 adopting a network resistor as an example will be described.

### Embodiment 4

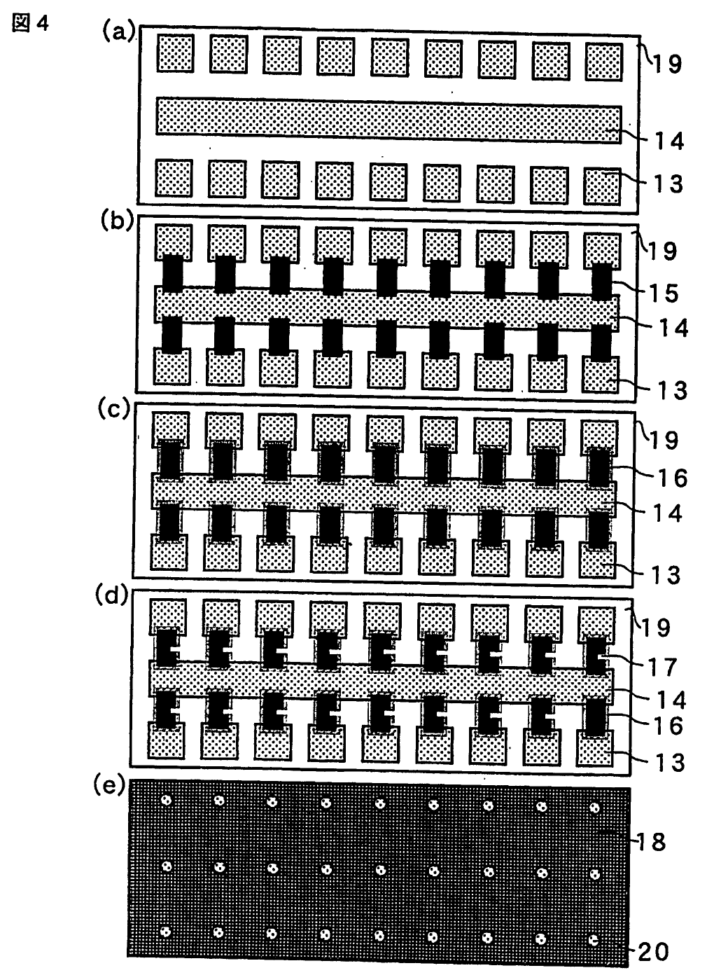

First, on a ceramic plate 19 made of aluminum shown in FIG. 4A, an Ag—Pd based conductive paste is screen printed and calcined thereafter, thereby obtaining electrodes 13 combining lands 20 and a common electrode 14 combining lands 20 for a resistor element (FIG. 4A). Next, a metal graze based resistive paste having ruthenium oxide and a glass frit as main ingredients is screen printed to be in contact with both the common electrode 14 and the electrodes 13, and thereafter it is calcined to obtain resistors 15 (FIG. 4B). Next, a glass paste is screen printed so as to cover the resistors 15, which is calcined thereafter to obtain glass 16 films (FIG. 4C). Next, in order to set the resistance value of a resistor element constituted of the electrodes 13, the common electrode 14 and the resistors 15 to a desired value, a step of forming trimming trenches 17 on the resistors 15 by laser irradiation for adjusting the resistance value is carried out (FIG. 4D). At this time, the films of the glasses 16 operate to prevent damage to all the resistors 15 as much as possible. Next, in order to protect the entire resistor element, an overcoat 18 is screen printed by an aromatic epoxy resin based paste, and thereafter the epoxy resin paste is cured by heating (FIG. 4E). When arranging the overcoat 18, necessary land 20 parts of the electrodes 13 and the common electrode 14 are exposed (FIG. 4E).

By performing the steps shown in FIGS. 4A to 4E, the ceramic plate 19 with a network resistor element on which only the lands 20 are exposed as conductive materials (terminals) can be obtained. Thereafter, by undergoing the steps of forming the bumps 7 which are described above and shown in FIGS. 1A to 1F, a network resistor according to the present invention can be obtained.

In the embodiment 4, the network resistor is shown as a circuit element, but it is needless to mention that the present invention is not limited thereto. It may be applied to a multiple resistor, a multiple capacitor, a network capacitor, a network element composed of two or more elements selected from a capacitor, a resistor element and an inductor element, and the like. For example, it may be also applied to a so-called CR component combining a resistor element and a capacitor.

Also, it is needless to mention that the bumps 7 formed in the fourth embodiment are preferred to have a truncated cone or truncated pyramid shape with a small tip because of the same reasons as described above. Other preferable conditions regarding the bumps 7 also apply to the fourth embodiment because they are in common in terms of the function as terminals of an electronic component. Further, not limited to the ceramic plate, these circuit elements may be formed on a printed circuit board 8 that is an epoxy based resin formed body with glass fiber being mixed therein, or the like. Also, as the electronic component produced in the fourth embodiment, it is needless to mention that the above-described anisotropic conductive material 2 can be used to form a package.

### INDUSTRIAL AVAILABILITY

According to the present invention, flip-chip mounting with a shortened distance between bumps can be realized. Accordingly, it becomes possible to miniaturize a flip-chip mounting electronic component.

1. A flip-chip mounting electronic component, comprising:
a plurality of terminals dotted on a mounting face; and
a plurality of conductors formed on said terminals,
said conductors being formed as remaining parts from growing formation and/or removal, all the sums of heights of said terminals and said conductors thereon being substantially equal, and tips of said conductors having a substantially flat face.

2. The flip-chip mounting electronic component according to claim 1,
wherein each of said conductors has a truncated cone or a truncated pyramid shape with a small tip.

3. An electronic component, comprising:
a circuit element and a plurality of terminals formed on a ceramic plate face; and
conductors formed on said terminals,
said conductors being formed as remaining parts from growing formation and/or removal, all the sums of heights of said terminals and said conductors thereon being substantially equal, and tips of said conductors having a substantially flat face.

4. The electronic component according to claim 3,
wherein each of said conductors has a truncated cone or a truncated pyramid shape with a small tip.

5. The electronic component according to claim 3,
wherein said circuit element is a multiple or a network resistor or capacitor, or a network element composed of two or more elements selected from a capacitor, a resistor element and an inductor element.

6. A method for producing a flip-chip mounting electronic component having a plurality of terminals dotted on a mounting face and a plurality of conductors formed on the terminals, comprising the steps of:
coating the mounting face with a conductor having a predetermined thickness;
masking corresponding positions for the terminal parts on the conductor surface; and
removing the conductor except the mask parts, the coating, masking and removing steps being carried out in the stated order.

7. A circuit board, comprising:
a plurality of flip-chip mounting lands dotted on a mounting face; and
a plurality of conductors formed on said terminals,
said conductors being formed as remaining parts from growing formation and/or removal, all the sums of heights of said lands and heights of said conductors thereon being substantially equal, and tips of said conductors have having a substantially flat face.

8. The circuit board according to claim 7,
wherein each of said conductors has a truncated cone or a truncated pyramid shape with a small tip.

9. A method for producing a circuit board having a plurality of flip-chip mounting lands dotted on a mounting face, comprising the steps of:
coating the mounting face with a conductor having a predetermined thickness;
masking corresponding positions for the lands on the conductor surface; and
removing the conductor except the mask parts, the coating, masking and removing steps being carried out in the stated order.

10. A method for producing a package in which mounting face terminal parts of a flip-chip mounting electronic component and/or flip-chip mounting lands of a circuit board mounting face have conductors, the method comprising:
forming the conductors as remaining parts from growing formation and/or removal; and
securing the conductors of the circuit board and the electronic component or the conductors of the electronic component and the circuit board with solder or anisotropic conductive material.

11. The method for producing a package according to claim 10,
wherein the conductors are constituted of copper and on surfaces thereof a nickel layer and a gold layer are formed in the stated order, and the securing step is carried out by fixing force of solder.
